(19) United States
(12) Patent Application Publication
(10) Pub. No.: US 2010/0135507 A1
(43) Pub. Date: Jun. 3, 2010

(54) Clipping prevention device and clipping prevention method

(75) Inventors: Yasuyuki Kino, Tokyo (JP); Tokihiko Sawashi, Tokyo (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 12/590,618

(22) Filed: Nov. 10, 2009

(30) Foreign Application Priority Data
Dec. 2, 2008 (JP) P2008-307523

(51) Int. Cl. H03G 7/00; G06F 17/00; G10L 19/00

(52) U.S. Cl. 381/106; 700/94; 704/500; 704/E19.001

(57) ABSTRACT

A clipping prevention device, includes: a compression section adapted to compress an input digital audio signal level; a digital-analog conversion section adapted to operate at a predetermined first operating voltage and convert the digital audio signal into an analog audio signal; an electronic volume control adapted to operate at a second operating voltage and amplify or attenuate the analog audio signal with a user-changeable amplification factor; and a control section adapted to calculate a clipping level based on the maximum amplification factor of the electronic volume control and the user-changeable amplification factor, the maximum amplification factor being determined when the analog audio signal at the maximum signal level is amplified to the maximum signal level, and also adapted to control the compression section so that the signal is compressed so as to prevent clipping of the analog audio signal amplified or attenuated by the electronic volume control.

### BACKGROUND OF THE INVENTION

1. Field of the Invention

The present invention relates to a clipping prevention device and clipping prevention method and is suitably applied, for example, to a vehicle-mounted car audio device.

2. Description of the Related Art

An existing car audio device has an electronic volume control adapted to increase and reduce the level of an analog audio signal. Such a device uses the electronic volume control to amplify or attenuate the analog audio signal with the amplification factor appropriate to the user's rotation of an operator.

In such car audio devices, the analog audio signal from the electronic volume control is monitored, for example, by a microcomputer.

Then, if the microcomputer of such a car audio device determines that the analog audio signal from the electronic volume control has been clipped, the microcomputer performs feedback control so as to limit the gain of the electronic volume control.

This allows for the car audio device to produce an audio output appropriate to the analog audio signal from the speaker without clipping the same signal.

On the other hand, some digital amplifiers offer soft clipping by adding a compression characteristic to the digital audio signal amplified by a digital volume control (refer, for example, to Japanese Patent Laid-Open No. 2004-214843).

### SUMMARY OF THE INVENTION

Incidentally, the aforementioned car audio device uses a microcomputer to perform feedback control of the gain of the electronic volume control. Therefore, the gain can be controlled every period of the operating clock of the microcomputer or, for example, 10 ms. As a result, gain control at a faster rate is impossible.

Further, because the car audio device is unable to perform feedback control faster than the clock period of the operating clock of the microcomputer, the gain of the electronic volume control changes in a step-like manner according to the operating clock of the microcomputer. This gives a sense of discomfort to the user when he or she listens to the sound produced by the speaker.

The present invention has been made in light of the foregoing, and there is a need for the present invention to propose a clipping prevention device and clipping prevention method for providing fast gain control of the audio device without giving a sense of discomfort to the user.

A clipping prevention device for solving the above problem includes a compression section, a digital-analog conversion section, an electronic volume control and a control section. The compression section compresses the level of an input digital audio signal. The digital-analog conversion section operates at a predetermined first operating voltage and converts the digital audio signal, compressed by the compression section, into an analog audio signal. The electronic volume control operates at a second operating voltage higher than the first operating voltage and amplifies or attenuates the analog audio signal with a user-changeable amplification factor appropriate to the user's rotation of an operator. The control section calculates a clipping level based on a maximum amplification factor of the electronic volume control and the user-changeable amplification factor. The maximum amplification factor of the electronic volume control is determined when the analog audio signal at the maximum signal level based on the first operating voltage is amplified to the maximum signal level based on the second operating voltage. The control section controls the compression section so that the signal is compressed according to the clipping level, thus preventing clipping of the analog audio signal amplified or attenuated by the electronic volume control.

Further, a clipping prevention method according to the present embodiment includes a compression step, a digital-analog conversion step, an amplification/attenuation step and a control step. The compression step compresses the level of an input digital audio signal using a compression section. The digital-analog conversion step converts the digital audio signal, compressed by the compression section, into an analog audio signal using a digital-analog conversion section which operates at a predetermined first operating voltage. The amplification/attenuation step amplifies or attenuates the analog audio signal with a user-changeable amplification factor appropriate to the user's rotation of an operator with an electronic volume control which operates at a second operating voltage higher than the first operating voltage. The control step calculates a clipping level based on a maximum amplification factor of the electronic volume control and the user-changeable amplification factor. The maximum amplification factor of the electronic volume control is determined when the analog audio signal at the maximum signal level based on the first operating voltage is amplified to the maximum signal level based on the second operating voltage. The control step controls the compression section so that the signal is compressed according to the clipping level, thus preventing clipping of the analog audio signal amplified or attenuated by the electronic volume control.

This permits compression of the digital audio signal according to the clipping level based on the user-changeable amplification factor and maximum amplification factor, thus ensuring faster gain control than the gain control of the analog audio signal and preventing clipping of the analog audio signal outputted from the electronic volume control.

The present embodiment allows for compression of a digital audio signal according to the clipping level based on the user-changeable amplification factor and maximum amplification factor, thus ensuring faster gain control than the gain control of the analog audio signal and preventing clipping of the analog audio signal outputted from the electronic volume control. This makes it possible to provide a clipping prevention device and clipping prevention method capable of providing fast gain control of the audio device without giving a sense of discomfort to the user.

### BRIEF DESCRIPTION OF THE DRAWINGS

FIG. 1 is a schematic diagram illustrating a car audio device according to a first embodiment;

FIG. 2 is a schematic diagram illustrating the relationship between the levels of digital audio signals outputted from a post-processing section and inputted to a D/A converter in an existing car audio device;

FIGS. 3A to 3E are schematic diagrams illustrating the relationship between the input and output levels of an electronic volume control in an existing car audio device;

FIG. 4 is a schematic diagram illustrating the configuration of a pattern table;

FIG. 5 is a schematic diagram illustrating the configuration of compression pattern 6 (+5 dB);

FIG. 6 is a schematic diagram illustrating the relationship between the input and output levels of an amplification unit according to the first embodiment;

FIG. 7 is a schematic diagram illustrating the configuration of compression pattern 11 (+10 dB);

FIG. 8 is a schematic diagram illustrating the relationship between the input and output levels of the amplification unit according to the first embodiment;

FIG. 9 is a flowchart used to describe the clipping prevention process steps according to the first embodiment;

FIGS. 10A and 10B are schematic diagrams illustrating the comparison of the relationships between the analog audio signals before and after the electronic volume control;

FIG. 11 is a schematic diagram illustrating the configuration of the car audio device according to a second embodiment;

FIG. 12 is a schematic diagram illustrating the configuration of compression pattern 1 (+0 dB);

FIG. 13 is a schematic diagram illustrating the relationship between the input and output levels of a variable digital volume control (+) and compressor according to the second embodiment;

FIG. 14 is a schematic diagram illustrating the relationship between the input and output levels of a compressor unit according to the second embodiment;

FIG. 15 is a schematic diagram illustrating the relationship between the input and output levels of the amplification unit according to the second embodiment;

FIG. 16 is a flowchart used to describe the clipping prevention process steps according to the second embodiment;

FIG. 17 is a schematic diagram illustrating the configuration of the car audio device according to a third embodiment;

FIG. 18 is a schematic diagram illustrating the relationship between the input and output levels of the compressor unit according to the third embodiment;

FIG. 19 is a schematic diagram illustrating the relationship between the input and output levels of the amplification unit according to the third embodiment;

FIG. 20 is a flowchart used to describe the clipping prevention process steps according to the third embodiment;

FIG. 21 is a schematic diagram illustrating the configuration of the car audio device according to other embodiment; and

FIG. 22 is a flowchart used to describe the clipping prevention process steps according to the other embodiment.

### DETAILED DESCRIPTION OF THE PREFERRED EMBODIMENTS

The best modes for carrying out the present invention (hereinafter referred to as the embodiments) will be described below. The description will be given in the following order:

1. First Embodiment

2. Second Embodiment

3. Third Embodiment

4. Other Embodiments

### 1. First Embodiment

### 1-1. Configuration of the Car Audio Device

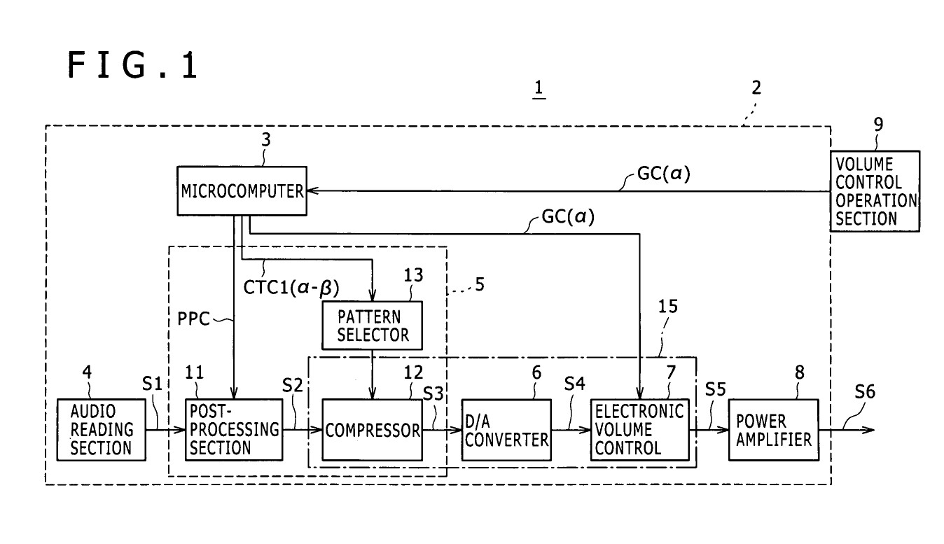

As illustrated in FIG. 1, a car audio device 1 is powered by a battery of about 12 V (not shown).

At this time, a microcomputer 3, audio reading section 4, DSP (Digital Signal Processor) 5 and D/A (Digital-to-Analog) converter 6 of the car audio device 1 are designed to operate, for example, at about 3.3 V for power saving purposes. On the other hand, an electronic volume control 7 of the same device 1 is designed to operate at about 10 V, and a power amplifier 8 thereof at about 12 V. Incidentally, we assume that the operating voltage of the power amplifier 8 of the car audio device 1 remains unchanged.

A volume control operation section 9 includes, for example, a rotatable operator provided on the front side of a body section 2 and accepts the user's rotation of the operator.

The microcomputer 3 is provided in the body section

2. The microcomputer 3 includes a CPU (Central Processing Unit), ROM (Read Only Memory) and RAM (Random Access Memory).

In the car audio device 1, the microcomputer 3 loads the operating system from the ROM into the RAM to control the car audio device 1 as a whole according to the operating system. The microcomputer 3 also loads a variety of application programs from the ROM into the RAM to execute various processes according to the application programs.

To reproduce music content stored in a medium such as a CD (Compact Disc) or external USB (Universal Serial Bus) memory, the car audio device 1 uses the audio reading section to read a digital audio signal S1 of the music content. Then, the audio reading section 4 outputs the digital audio signal S1, read from the CD, USB memory or other medium, to a post-processing section 11 of the DSP 5.

On the other hand, the microcomputer 3 sends a post-processing command PPC to the post-processing section 11 of the DSP 5. The post-processing command PPC is adapted to apply the sound quality effects, set in advance by the user, to the digital audio signal S1.

Further, the microcomputer 3 acquires an amplification factor specification command GC from the volume control operation section 9 and sends the same command GC to the electronic volume control 7. The amplification factor specification command GC indicates an amplification factor (hereinafter referred to as the user-changeable amplification factor) α in the range from −20 dB to 20 dB according to the user's rotation of the volume control operation section 9.

Still further, the microcomputer 3 sends a clipping level transmission command CTC1 (described later), based on the amplification factor specification command GC acquired from the volume control operation section 9, to a pattern selector 13 of the DSP 5.

The pattern selector 13 sends a predetermined compression pattern (described later) to a compressor 12 based on the clipping level transmission command CTC1 supplied from the microcomputer 3.

The post-processing section 11 applies post-processing such as equalizer, time alignment, bass, treble and loudness to the digital audio signal S1 inputted from the audio reading section 4 based on the post-processing command PPC supplied from the microcomputer 3. The same section 11 outputs a resultant digital audio signal S2 to the compressor 12.

The compressor 12 performs level compression of the digital audio signal S2 inputted from the post-processing section 11 based on the compression pattern supplied from the pattern selector 13. The level compression will be described later. The compressor 12 outputs a resultant digital audio signal S3 to the D/A converter 6.

The D/A converter 6 converts the digital audio signal S3 inputted from the compressor 12 into an analog form and outputs a resultant analog audio signal S4 to the electronic volume control 7.

Therefore, the electronic volume control 7 amplifies the analog audio signal S4 inputted from the D/A converter 6 with the user-changeable amplification factor α indicated by the amplification factor specification command GC and outputs a resultant analog audio signal S5 to the power amplifier 8.

The power amplifier 8 amplifies the analog audio signal S5 inputted from the electronic volume control 7 with the predetermined amplification factor and outputs a resultant analog audio signal from an external speaker (not shown) in the form of an audio sound.

As described above, the car audio device 1 outputs the sound appropriate to the music content stored in a CD, USB memory or other medium via a speaker, thus allowing for the user to listen to the audio sound.

Incidentally, the level of the analog audio signal S4 outputted from the D/A converter 6 depends on the operating voltage of the same converter 6. Further, the levels of the analog audio signal S5 outputted from the electronic volume control 7 and an analog audio signal S6 outputted from the power amplifier 8 depend on the operating voltages of the electronic volume control 7 and power amplifier 8, respectively. Here, the full-bit digital audio signal S2 is defined to be 0 dB.

That is, when the full-bit digital audio signal S3 is inputted via the compressor 12, the D/A converter 6 outputs the same signal S3 as the analog audio signal S4 of 0 dB which is appropriate to the operating voltage of the D/A converter 6.

Further, when amplifying the analog audio signal S4 inputted from the D/A converter 6, the electronic volume control 7 can amplify the same signal S4 of 0 dB to 10 dB which is appropriate to the operating voltage of the electronic volume control 7 without clipping.

Here, the amplification factor adapted to amplify the analog audio signal S4 of 0 dB, without clipping, to 10 dB with the electronic volume control 7 is referred to as the maximum amplification factor for 0 dB reproduction.

Incidentally, the electronic volume control 7 can amplify the analog audio signal S4 with an amplification factor, for example, from −20 dB to +20 dB, as described above.

The reason for this is as follows. That is, assuming that the digital audio signal S1 of less than 0 dB is supplied, even if the electronic volume control 7 amplifies the analog audio signal S4, for example, with an amplification factor of 10 dB or more, 10 dB will not be exceeded. Therefore, the analog audio signal S4 can be amplified without clipping.

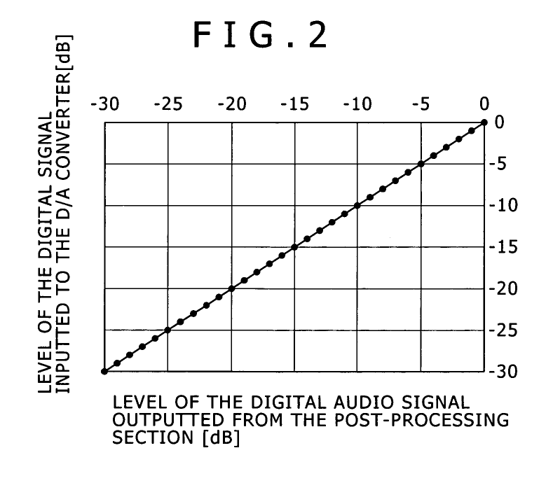

In an existing car audio device devoid of the compressor 12 and pattern selector 13 according to the present embodiment, however, the digital audio signal S2 outputted from the post-processing section 11 is inputted to the D/A converter 6 in an as-is manner without being compressed in level as illustrated in FIG. 2.

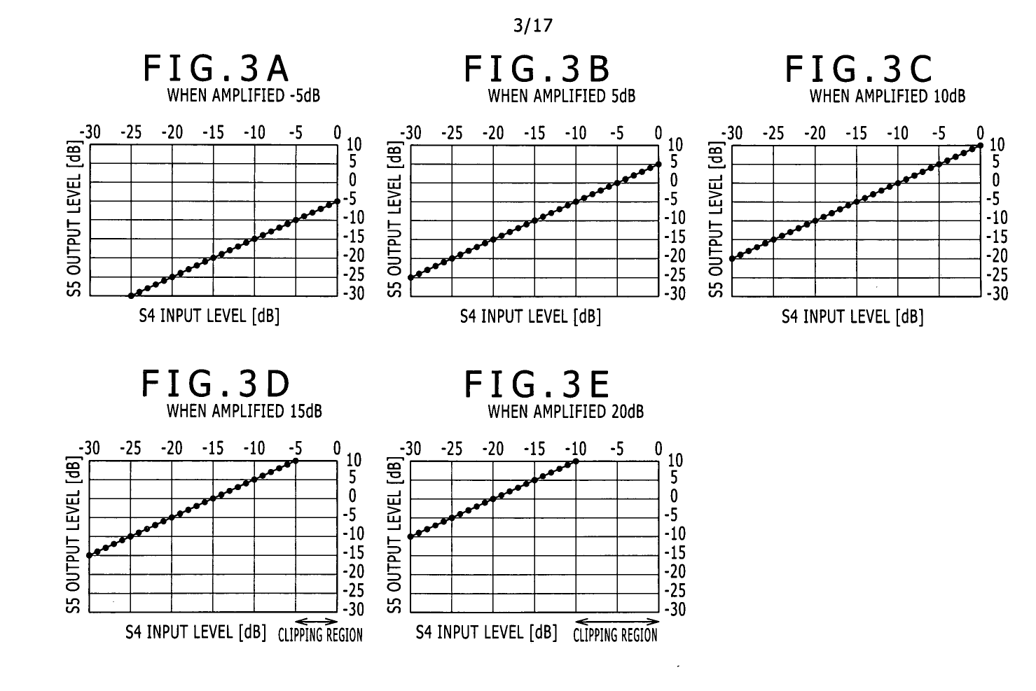

Here, FIGS. 3A to 3E illustrate the input and output levels of the electronic volume control 7 of an existing car audio device when the analog audio signal S4 is amplified, for example, −5, +5, +10, +15 and +20 dB.

Incidentally, the level of the analog audio signal S4 inputted to the electronic volume control 7 is referred to as the S4 input level, and the level of the analog audio signal S5 outputted from the electronic volume control 7 as the S5 output level.

Therefore, when the S4 input level is amplified −5, +5 and +10 dB by the electronic volume control 7 in an existing car audio device (FIGS. 3A to 3C), the S5 output level will in no case exceed 10 dB even if the S4 input level is 0 dB. Therefore, an existing car audio device never clips the analog audio signal S5 outputted from the electronic volume control 7.

However, when the S4 input level is amplified +15 dB by the electronic volume control 7 in an existing car audio device (FIG. 3D), the S5 output level will exceed 10 dB and therefore the analog audio signal S5 will be clipped if the S4 input level is −5 dB or greater. Incidentally, the region where the S5 output level exceeds 10 dB is referred to as the clipping region. In this case, therefore, the clipping region is from −5 dB to 0 dB of the S4 input level.

Further, when the S4 input level is amplified +20 dB by the electronic volume control 7 in an existing car audio device (FIG. 3E), the S5 output level will exceed 10 dB and therefore the analog audio signal S5 will be clipped if the S4 input level is −10 dB or greater. In this case, therefore, the clipping region is from −10 dB to 0 dB of the S4 input level.

When amplifying the analog audio signal S4 with the electronic volume control 7, such an existing car audio device may clip the analog audio signal S5 depending on the relationship between the level of the analog audio signal S4 and the user-changeable amplification factor α.

### 1-2. Clipping Prevention Process

For this reason, the car audio device 1 (FIG. 1) has the compressor 12 and pattern selector 13 to perform a clipping prevention process, thus preventing clipping of the analog audio signal S5 outputted from the electronic volume control 7.

More specifically, the car audio device 1 (FIG. 1) of the present embodiment has a maximum amplification factor for 0 dB reproduction β stored in the ROM of the microcomputer 3 or other medium in advance.

If the microcomputer 3 acquires the amplification factor specification command GC indicating that the user-changeable amplification factor α is, for example, +15 dB according to the user's rotation of the volume control operation section 9, the microcomputer 3 performs the following process.

That is, the microcomputer 3 subtracts 10 dB, the maximum amplification factor for 0 dB reproduction β stored in advance in the ROM, from +15 dB, the user-changeable amplification factor α indicated by the amplification factor specification command GC acquired from the volume control operation section 9. Then, the microcomputer 3 sends the clipping level transmission command CTC1 to the pattern selector 13 of the DSP 5. The same command CTC1 indicates a set clipping level (α−β) obtained by subtracting the maximum amplification factor for 0 dB reproduction β from the user-changeable amplification factor α or +5 dB.

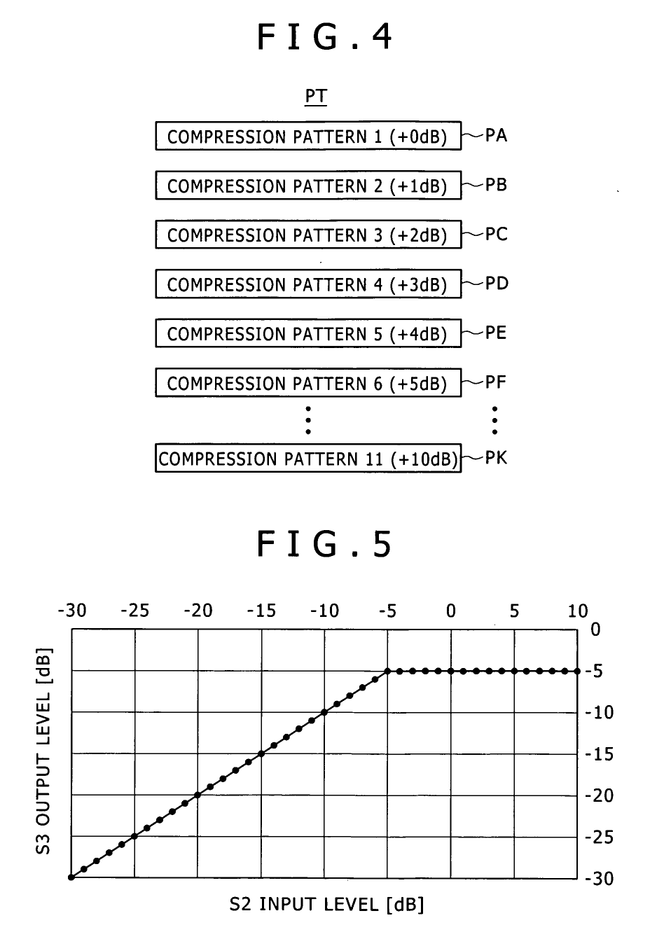

The pattern selector 13 has a pattern table PT which contains 11 compression patterns from compression patterns 1 (+0 dB) PA to 11 (+10 dB) PK as illustrated in FIG. 4.

The pattern selector 13 selects the compression pattern 6 (+5 dB) PF as illustrated in FIG. 5 which is appropriate to the set clipping level (α−β), indicated by the clipping level transmission command CTC1 supplied from the microcomputer 3, or +5 dB. The pattern selector 13 sends the compression pattern 6 (+5 dB) PF to the compressor 12.

Here, in the compression pattern 6 (+5 dB) PF, the level of the digital audio signal S2 inputted to the compressor 12 is referred to as the S2 input level, and the level of the digital audio signal S3 outputted from the compressor 12 as the S3 output level.

The compressor 12 compresses the level of the digital audio signal S2 inputted from the post-processing section 11 based on the compression pattern 6 (+5 dB) PF.

More specifically, if the S2 input level is −5 dB or less, the compressor 12 does not compress the level of the digital audio signal S2 and outputs the digital audio signal S3 at the S3 output level which is the same level as the S2 input level.

In contrast, if the S2 input level is greater than −5 dB, the compressor 12 compresses the level of the digital audio signal S2 to −5 dB and outputs the resultant digital audio signal S3 at the S3 output level of −5 dB.

As described above, the compressor 12 adaptively compresses the signal level according to the level (S2 input level) of the digital audio signal S2 inputted from the post-processing section 11.

The electronic volume control 7 amplifies the analog audio signal S4 with the user-changeable amplification factor α, indicated by the amplification factor specification command GC supplied from the microcomputer 3, or +15 dB. The analog audio signal S4 is inputted from the compressor 12 via the D/A converter 6.

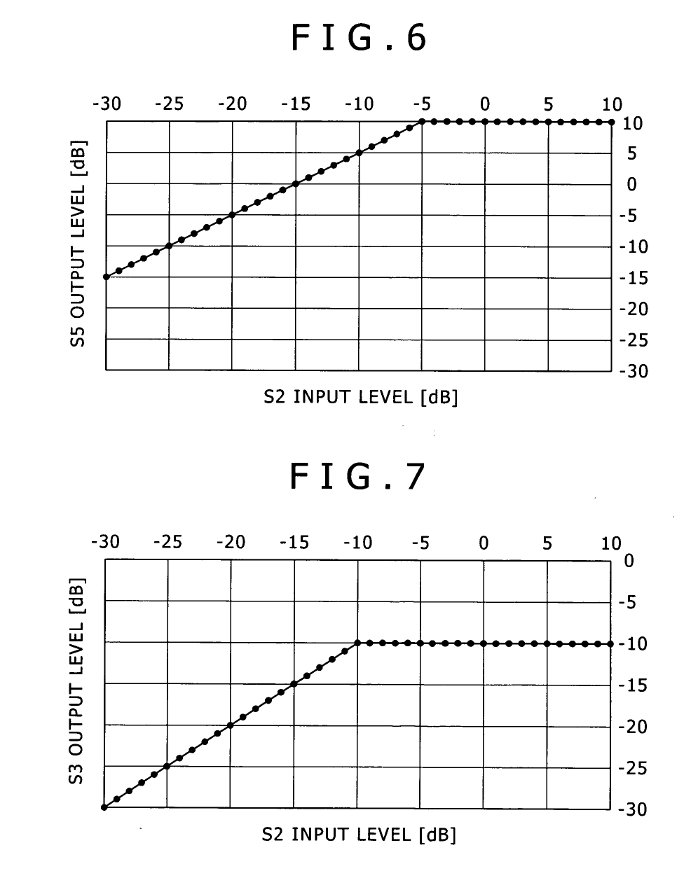

Here, FIG. 6 illustrates the input and output levels of an amplification unit 15 with the S2 input level representing the level of the digital audio signal S2 inputted to the amplification unit 15 and the S5 output level representing the level of the analog audio signal S5 outputted from the amplification unit 15. Incidentally, the amplification unit 15 includes the compressor 12, D/A converter 6 and electronic volume control 7.

As illustrated in FIG. 6, if the S2 input level is −5 dB or less, the amplification unit 15 does not compress the level of the digital audio signal S2 with the compressor 12 and outputs the analog audio signal S5 at the S5 output level obtained by amplifying the S2 input level +15 dB.

In contrast, if the S2 input level is greater than −5 dB, the amplification unit 15 compresses the level of the digital audio signal S2 to −5 dB with the compressor 12 first and then outputs the analog audio signal S5 at the S5 output level of 10 dB obtained by amplifying the S2 input level +15 dB with the electronic volume control 7.

A description will be given next of a case in which the user-changeable amplification factor α is set to +20 dB according to the user's rotation of the volume control operation section 9.

The microcomputer 3 acquires the amplification factor specification command GC indicating that the user-changeable amplification factor α is, for example, +20 dB according to the user's rotation of the volume control operation section 9.

At this time, the microcomputer 3 subtracts 10 dB, the maximum amplification factor for 0 dB reproduction β stored in advance in the ROM, from +20 dB, the user-changeable amplification factor α indicated by the amplification factor specification command GC acquired from the volume control operation section 9. The microcomputer 3 sends the clipping level transmission command CTC1 to the pattern selector 13 of the DSP 5. The same command CTC1 indicates the set clipping level (α−β), obtained by subtracting the maximum amplification factor for 0 dB reproduction β from the user-changeable amplification factor α, or +10 dB.

The pattern selector 13 selects, from the pattern table PT, the compression pattern 11 (+10 dB) PK illustrated in FIG. 7 based on the set clipping level (α−β), indicated by the clipping level transmission command CTC1 supplied from the microcomputer 3, or +10 dB. Then, the pattern selector 13 sends the compression pattern 11 (+10 dB) PK to the compressor 12.

The compressor 12 compresses the level of the digital audio signal S2 inputted from the post-processing section 11 based on the compression pattern 11 (+10 dB) PK.

More specifically, if the S2 input level is −10 dB or less, the compressor 12 does not compress the level of the digital audio signal S2 and outputs the digital audio signal S3 at the S3 output level which is the same level as the S2 input level.

In contrast, if the S2 input level is greater than −10 dB, the compressor 12 compresses the level of the digital audio signal S2 to −10 dB and then outputs the resultant analog audio signal S3 at the S3 output level of −10 dB.

The electronic volume control 7 amplifies the analog audio signal S4 with the user-changeable amplification factor α, indicated by the amplification factor specification command GC supplied from the microcomputer 3, or +20 dB. The analog audio signal S4 is inputted from the compressor 12 via the D/A converter 6.

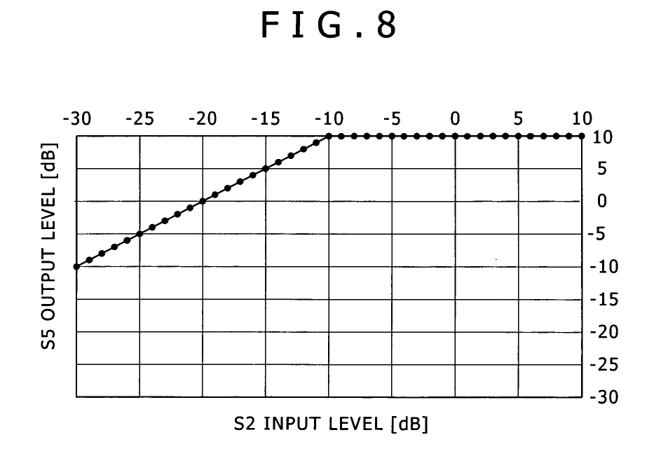

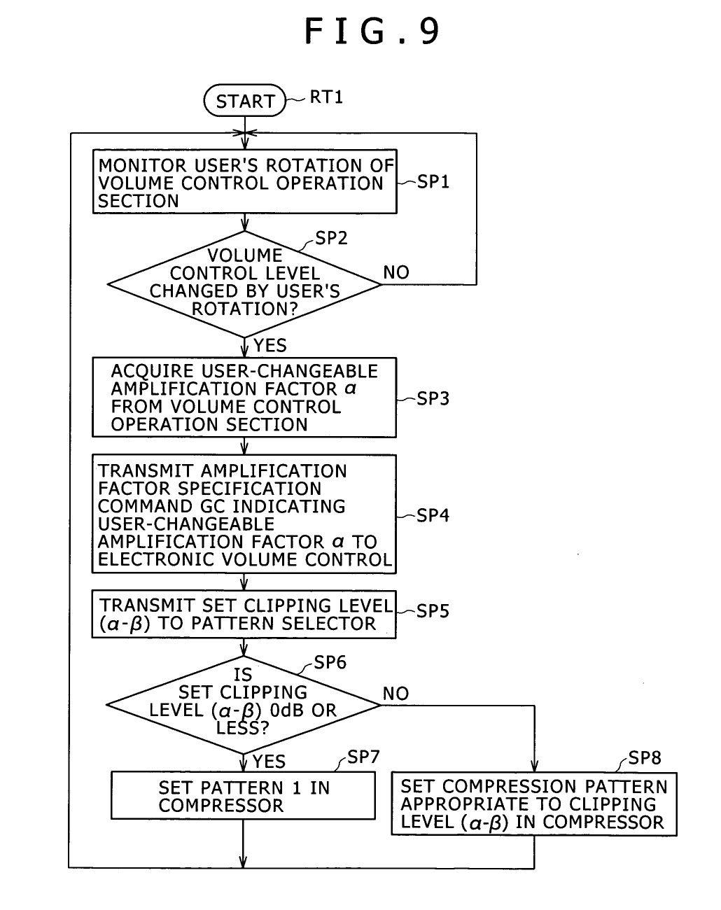

Here, FIG. 8 illustrates the input and output levels of the amplification unit 15 with the S2 input level representing the level of the digital audio signal S2 inputted to the amplification unit 15 and the S5 output level representing the level of the analog audio signal S5 outputted from the amplification unit 15.

As illustrated in FIG. 8, if the S2 input level is −10 dB or less, the amplification unit 15 does not compress the level of the digital audio signal S2 with the compressor 12 and outputs the analog audio signal S5 at the S5 output level obtained by amplifying the S2 input level +20 dB.

In contrast, if the S2 input level is greater than −10 dB, the amplification unit 15 compresses the level of the digital audio signal S2 to −10 dB with the compressor 12 first and then outputs the analog audio signal S5 at the S5 output level of 10 dB obtained by amplifying the S2 input level +20 dB with the electronic volume control 7.

As described above, the amplification unit 15 keeps the S5 output level at 10 dB or less even if the S2 input level is +15 dB or +20 dB, positively preventing clipping of the analog audio signal S5.

### 1-3. Clipping Prevention Process Steps

A detailed description will be given next of the steps for performing the above clipping prevention process with reference to the flowchart shown in FIG. 9. Practically, the microcomputer 3 begins with the initial step of a routine RT1. Next, the microcomputer 3 proceeds to step SP1 to monitor the user's rotation of the volume control operation section 9 and then proceeds on to step SP2.

In step SP2, the microcomputer 3 determines whether the volume control operation section 9 has been rotated by the user. If the result is negative in step SP2, this means that the volume control operation section 9 has not been rotated. At this time, the microcomputer 3 returns to step SP1 to wait until the volume control operation section 9 is rotated by the user.

In contrast, when the result is affirmative in step SP2, this means that the user-changeable amplification factor α has been changed as a result of the rotation of the volume control operation section 9 by the user. At this time, the microcomputer 3 proceeds to step SP3.

Incidentally, when the microcomputer 3 determines in step SP2 for the first time after initiating the clipping prevention process whether the volume control operation section 9 has been rotated by the user, it is assumed that the result is affirmative. As a result, the microcomputer 3 proceeds to next step SP3.

In step SP3, the microcomputer 3 acquires the amplification factor specification command GC indicating the user-changeable amplification factor α from the volume control operation section 9 and proceeds to next step SP4.

In step SP4, the microcomputer 3 sends the amplification factor specification command GC acquired from the volume control operation section 9 to the electronic volume control 7 to finalize the amplification factor of the same control 7. Then, the microcomputer 3 proceeds to next step SP5.

In step SP5, the microcomputer 3 subtracts the maximum amplification factor for 0 dB reproduction β stored in advance in the ROM from the user-changeable amplification factor α indicated by the amplification factor specification command GC acquired from the volume control operation section 9.

Then, the microcomputer 3 sends the clipping level transmission command CTC1 to the pattern selector 13 of the DSP 5. The same command CTC1 indicates the set clipping level (α−β) obtained by subtracting the maximum amplification factor for 0 dB reproduction β from the user-changeable amplification factor α. Then, the microcomputer 3 proceeds to next step SP6.

In step SP6, the pattern selector 13 determines whether the set clipping level (α−β) indicated by the clipping level transmission command CTC1 supplied from the microcomputer 3 is 0 dB or less. The pattern selector 13 proceeds to next step SP7 when the result is affirmative.

In step SP7, the pattern selector 13 reads the compression pattern 1 (+0 dB) PA from the pattern table PT (FIG. 4) and sends the same pattern PA to the compressor 12. By doing so, the pattern selector 13 sets the compression pattern 1 (+0 dB) PA in the compressor 12 and then returns to step SP1.

In contrast, if the result is negative in step SP6, the pattern selector 13 proceeds to step SP8. In step SP8, the pattern selector 13 reads one of the compression patterns 1 (+0 dB) PA to 11 (+10 dB) PK appropriate to the set clipping level (α−β) indicated by the clipping level transmission command CTC1 supplied from the microcomputer 3.

Then, the pattern selector 13 sends the read compression pattern or one of the compression patterns 1 (+0 dB) PA to 11 (+10 dB) PK to the compressor 12. By doing so, the pattern selector 13 sets one of the compression patterns 1 (+0 dB) PA to 11 (+10 dB) PK in the compressor 12 and then returns to step SP1.

As described above, the car audio device 1 repeats steps SP1 to SP8 from power-on to power-off, thus preventing clipping of the analog audio signal S5 from the electronic volume control 7 at all times.

### 1-4. Operation and Effects

In the above first embodiment, the car audio device uses the pattern selector 13 to select one of the compression patterns 1 (+0 dB) PA to 11 (+10 dB) PK appropriate to the set clipping level (α−β) obtained by subtracting the maximum amplification factor for 0 dB reproduction β from the user-changeable amplification factor α.

Then, the car audio device 1 uses the compressor 12 to compress the level of the digital audio signal S2 based on the compression pattern selected by the pattern selector 13 or one of the compression patterns 1 (+0 dB) PA to 11 (+10 dB) PK.

Next, the car audio device 1 uses the D/A converter 6 to convert the digital audio signal S3, compressed in signal level by the compressor 12, into an analog form.

Then, the car audio device 1 uses the electronic volume control 7 to amplify the analog audio signal S4, converted by the D/A converter 6, with the user-changeable amplification factor α appropriate to the user's rotation of the volume control operation section 9.

Therefore, the car audio device 1 compresses the signal level based on the user-changeable amplification factor α and maximum amplification factor for 0 dB reproduction β, irrespective of the level of the digital audio signal S1 and user-changeable amplification factor α of the electronic volume control 7. This permits positive prevention of the clipping of the analog audio signal S5 outputted from the electronic volume control 7.

Further, the car audio device 1 can prevent clipping of the analog audio signal S5 outputted from the electronic volume control 7. Moreover, the power amplifier 8 is free from voltage variations. As a result, the same device 1 can also prevent clipping of the analog audio signal S6 outputted from the power amplifier 8. This makes it possible for the car audio device 1 to prevent clipping of the sound which will be outputted via the speaker.

Still further, the car audio device 1 can compress the level of the digital audio signal S2 at the sampling rate of the DSP 5 rather than performing feedback control by monitoring the analog audio signal S6 outputted from the power amplifier 8. This ensures fast gain control, thus allowing for gain control without giving a sense of discomfort to the user.

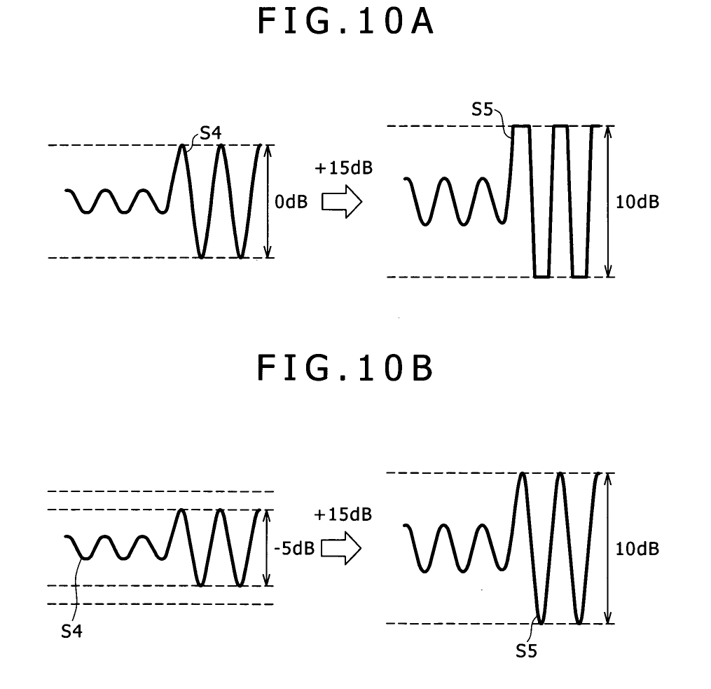

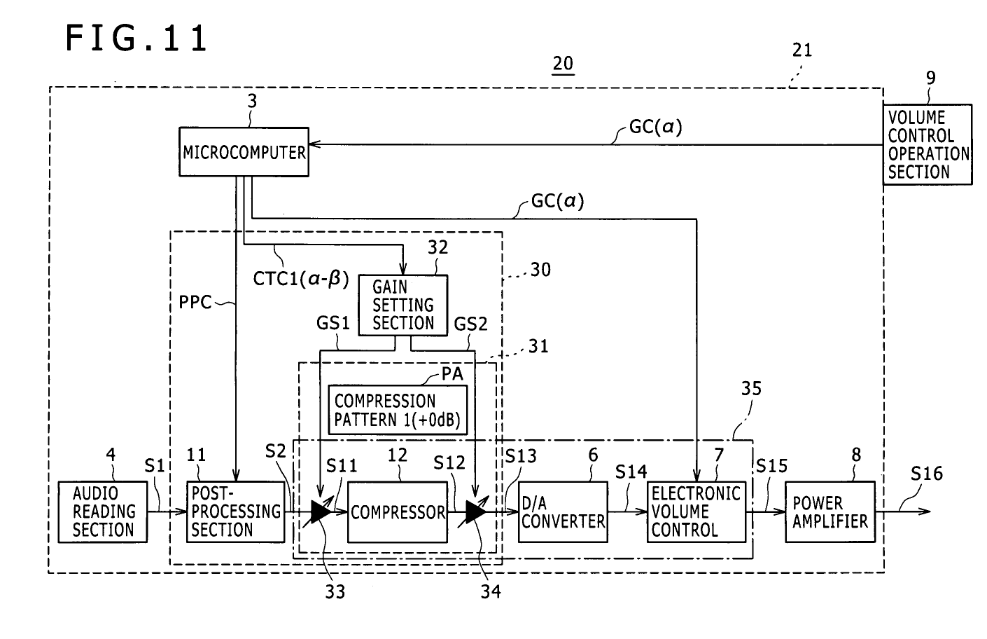

Incidentally, in an existing car audio device devoid of the compressor 12 or pattern selector 13, when the analog audio signal S4 outputted from the D/A converter 6 is sufficiently smaller than 0 dB as illustrated in FIG. 10A, the analog audio signal S5 will not be clipped even if the analog audio signal S4 is amplified, for example, +15 dB by the electronic volume control 7.

In an existing car audio device, however, when the analog audio signal S4 outputted from the D/A converter 6 is 0 dB, the analog audio signal S5 will exceed the maximum amplification factor for 0 dB reproduction β or 10 dB and therefore be clipped if the analog audio signal S4 is amplified, for example, +15 dB by the electronic volume control 7.

In contrast, the car audio device 1 of the present invention sets the compressor 12 to one of the compression patterns 1 (+0 dB) PA to 11 (+10 dB) PK appropriate to the set clipping level (α−β) to compress the level of the digital audio signal S2 with the compressor 12.

In the car audio device 1, therefore, when the analog audio signal S4 outputted from the D/A converter 6 is sufficiently smaller than 0 dB as illustrated in FIG. 10B, the analog audio signal S5 will not be clipped even if the analog audio signal S4 which has not been compressed by the compressor 12 is amplified, for example, +15 dB by the electronic volume control 7.

Further, in the car audio device 1, when the digital audio signal S2 is 0 dB, the compressor 12 compresses the level of the same signal S2, thus bringing the level of the analog audio signal outputted from the D/A converter 6 to −5 dB.

In the car audio device 1, therefore, even when the digital audio signal S2 is 0 dB, the analog audio signal S5 obtained by amplifying the analog audio signal S4 with the electronic volume control 7, for example, +15 dB will not exceed the maximum amplification factor for 0 dB reproduction β or 10 dB, positively preventing clipping of the same signal S5.

The car audio device 1 configured as described above compresses the level of the digital audio signal S2 based on the compression pattern appropriate to the set clipping level (α−β) obtained by subtracting the maximum amplification factor for 0 dB reproduction β from the user-changeable amplification factor α. This ensures fast gain control without giving a sense of discomfort to the user or causing clipping.

### 2. Second Embodiment

### 2-1. Configuration of the Car Audio Device

As illustrated in FIG. 11 in which like components as those in FIG. 1 are denoted by the same reference symbols, a car audio device 20 according to a second embodiment has a DSP 30 rather than the DSP 5 provided in the first embodiment. Incidentally, we assume that the operating voltage of the power amplifier 8 of the car audio device 20 remains unchanged.

The DSP 30 includes the post-processing section 11, a compressor unit 31 and a gain setting section 32. An amplification unit 35 includes a variable digital volume control (+) 33, the compressor 12, a variable digital volume control (−) 34, the D/A converter 6 and the electronic volume control 7.

To reproduce music content stored in a medium such as a CD or external USB memory, the car audio device 20 uses the audio reading section 4 to read the digital audio signal S1 of the music content. Then, the audio reading section 4 outputs the digital audio signal S1, read from the CD, USB memory or other medium, to the post-processing section 11 of the DSP 30.

On the other hand, the microcomputer 3 sends the post-processing command PPC to the post-processing section 11 of the DSP 30. The post-processing command PPC is adapted to apply the sound quality effects, set in advance by the user, to the digital audio signal S1.

Further, the microcomputer 3 acquires the amplification factor specification command GC from the volume control operation section 9 and sends the same command GC to the electronic volume control 7. The amplification factor specification command GC indicates the user-changeable amplification factor α in the range from −20 dB to 20 dB according to the user's rotation of the volume control operation section 9.

Still further, the microcomputer 3 sends the clipping level transmission command CTC1 to the gain setting section 32 of the DSP 30. The same command CTC1 indicates the set clipping level (α−β) which is obtained by subtracting the maximum amplification factor for 0 dB reproduction β, stored in the ROM, from the user-changeable amplification factor α indicated by the amplification factor specification command GC from the volume control operation section 9.

As described later, the gain setting section 32 outputs gain signals GS1 and GS2 respectively to the variable digital volume control (+) 33 and variable digital volume control (−) 34 of the compressor unit 31 based on the clipping level transmission command CTC1 supplied from the microcomputer 3.

The post-processing section 11 applies post-processing to the digital audio signal S1 inputted from the audio reading section 4 based on the post-processing command PPC supplied from the microcomputer 3. The same section 11 outputs the resultant digital audio signal S2 to the variable digital volume control (+) 33.

The variable digital volume control (+) 33 amplifies the digital audio signal S2 inputted from the post-processing section 11 based on the gain signal GS1 supplied from the gain setting section 32 and outputs a resultant digital audio signal S11 to the compressor 12.

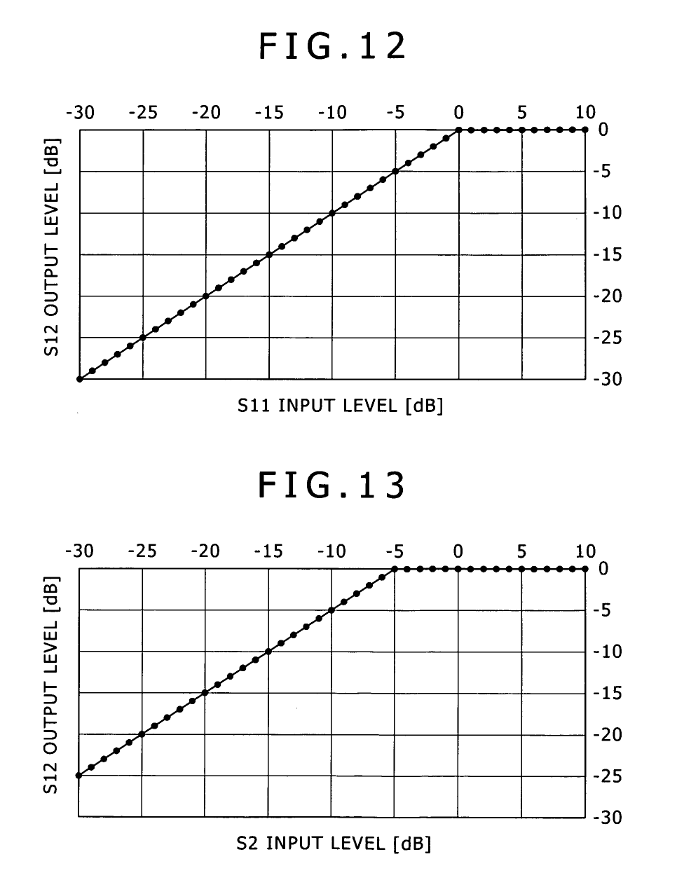

The compressor 12 compresses the level of the digital audio signal S11 inputted from the variable digital volume control (+) 33 using the compression pattern 1 (+0 dB) PA (FIG. 12) stored in the compressor unit 31. Then, the compressor 12 outputs a resultant digital audio signal S12, obtained by the signal level compression, to the variable digital volume control (−) 34.

The variable digital volume control (−) 34 amplifies the digital audio signal S12 inputted from the compressor 12 based on the gain signal GS2 supplied from the gain setting section 32 and outputs a resultant digital audio signal S13 to the D/A converter 6.

The D/A converter 6 converts the digital audio signal S13 inputted from the variable digital volume control (−) 34 into an analog form and outputs a resultant analog audio signal S14 to the electronic volume control 7.

The electronic volume control 7 amplifies the analog audio signal S14 inputted from the D/A converter 6 with the user-changeable amplification factor α indicated by the amplification factor specification command GC supplied from the microcomputer 3 and outputs a resultant analog audio signal S15 to the power amplifier 8.

The power amplifier 8 amplifies the analog audio signal S15 inputted from the electronic volume control 7 with a predetermined fixed amplification factor and outputs a resultant analog audio signal S16 obtained by the amplification from an external speaker (not shown) in the form of an audio sound.

As described above, the car audio device 20 outputs the audio sound appropriate to the music content stored in a CD, USB memory or other medium via a speaker, thus allowing for the user to listen to the audio sound.

### 2-2. Clipping Prevention Process

A description will be given next of a clipping prevention process adapted to prevent clipping of the analog audio signal S15 outputted from the electronic volume control 7 by way of a specific example.

If the microcomputer 3 acquires the amplification factor specification command GC indicating that the user-changeable amplification factor α is, for example, +15 dB according to the user's rotation of the volume control operation section 9, the microcomputer 3 performs the following process.

That is, the microcomputer 3 subtracts 10 dB, the maximum amplification factor for 0 dB reproduction β stored in advance in the ROM, from +15 dB, the user-changeable amplification factor α indicated by the amplification factor specification command GC acquired from the volume control operation section 9. Then, the microcomputer 3 sends the clipping level transmission command CTC1 to the gain setting section 32 of the DSP 30. The same command CTC1 indicates the set clipping level (α−β), obtained by subtracting the maximum amplification factor for 0 dB reproduction β from the user-changeable amplification factor α, or +5 dB.

The gain setting section 32 sets the set clipping level (α−β), indicated by the clipping level transmission command CTC1 supplied from the microcomputer 3, or +5 dB, as the gain of the variable digital volume control (+) 33. Then, the gain setting section 32 sends the gain signal GS1 to the variable digital volume control (+) 33. The same signal GS1 indicates the gain (+5 dB) of the variable digital volume control (+) 33.

The variable digital volume control (+) 33 amplifies the digital audio signal S2 inputted from the post-processing section 11 with the gain, indicated by the gain signal GS1 supplied from the gain setting section 32, or +5 dB and outputs the resultant digital audio signal S11 to the compressor 12.

The compressor 12 compresses the level of the digital audio signal S11 inputted from the variable digital volume control (+) 33 based on the compression pattern 1 (+0 dB) PA as illustrated in FIG. 12. Then, the compressor 12 outputs the resultant digital audio signal S12, obtained by the signal level compression, to the variable digital volume control (−) 34.

Here, FIG. 13 illustrates the input and output levels of the variable digital volume control (+) 33 with the S2 input level representing the level of the digital audio signal S2 inputted to the variable digital volume control (+) and the S12 output level representing the level of the digital audio signal S12 outputted from the variable digital volume control (+) 33 via the compressor 12.

That is, the compressor 12 compresses the level of the digital audio signal S11, amplified in advance +5 dB by the variable digital volume control (+) 33, based on the compression pattern 1 (+0 dB) PA.

Therefore, if the S2 input level is −5 dB or less, the compressor 12 outputs the digital audio signal S12 at the S12 output level obtained by amplifying the S2 input level 5 dB.

In contrast, if the S2 input level is greater than −5 dB, the compressor 12 compresses the level of the digital audio signal S2 to 0 dB according to the compression pattern 1 (+0 dB) PA and outputs the resultant digital audio signal S12 at the S12 output level of 0 dB.

On the other hand, the gain setting section 32 sets (−(α−β)) or −5 dB, the value obtained by multiplying the set clipping level (α−β) indicated by the clipping level transmission command CTC1 by −1, as the gain of the variable digital volume control (−) 34.

Then, the gain setting section 32 sends the gain signal GS2 to the variable digital volume control (−) 34. The same signal GS2 indicates the gain (−5 dB) of the variable digital volume control (−) 34.

The variable digital volume control (−) 34 amplifies the digital audio signal S12 inputted from the compressor 12 with the gain, indicated by the gain signal GS2 supplied from the gain setting section 32, or −5 dB. That is, the same control (−) 34 attenuates the same signal S12 5 dB. The same control (−) 34 outputs the resultant digital audio signal S13, obtained by amplifying (attenuating) the digital audio signal S12, to the D/A converter 6.

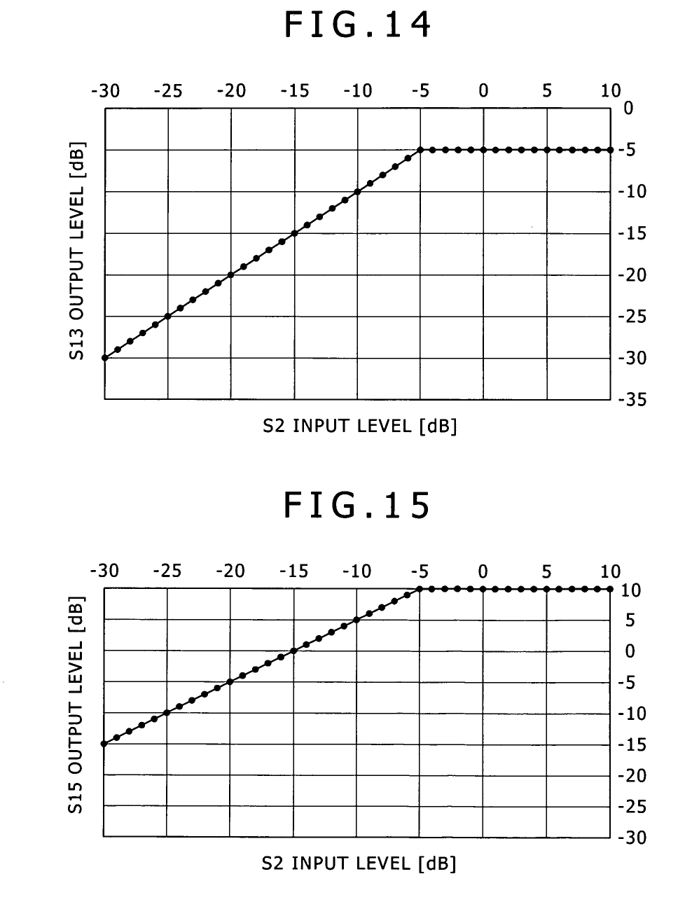

Here, FIG. 14 illustrates the input and output levels of the compressor unit 31 with the S2 input level representing the level of the digital audio signal S2 inputted to the compressor unit 31 and the S13 output level representing the level of the digital audio signal S13 outputted from the compressor unit 31.

As illustrated in FIG. 14, if the S2 input level is −5 dB or less, the compressor unit 31 outputs the digital audio signal S13 at the S13 output level which is the same level as the S2 input level.

In contrast, if the S2 input level is greater than −5 dB, the compressor unit 31 outputs the digital audio signal S13 at the S13 output level of −5 dB.

Then, the electronic volume control 7 amplifies the analog audio signal S14 inputted from the compressor unit 31 via the D/A converter 6 with the user-changeable amplification factor α, indicated by the amplification factor specification command GC supplied from the microcomputer 3, or +15 dB.

Here, FIG. 15 illustrates the input and output levels of the amplification unit 35 with the S2 input level representing the level of the digital audio signal S2 inputted to the amplification unit 35 and the S15 output level representing the level of the analog audio signal S15 outputted from the amplification unit 35.

As illustrated in FIG. 15, if the S2 input level is −5 dB or less, the amplification unit 35 does not compress the level of the digital audio signal S2 with the compressor unit 31 and outputs the analog audio signal S15 at the S15 output level obtained by amplifying the S2 input level +15 dB.

In contrast, if the S2 input level is greater than −5 dB, the amplification unit 35 compresses the level of the digital audio signal S2 to −5 dB with the compressor unit 31 first. Then, the amplification unit 35 outputs the analog audio signal S15 at the S15 output level of 10 dB obtained by amplifying the S2 input level +15 dB with the electronic volume control 7.

As described above, the amplification unit 35 does not amplify the S15 output level beyond 10 dB irrespective of the S2 input level, positively preventing clipping of the analog audio signal S15.

### 2-3. Clipping Prevention Process Steps

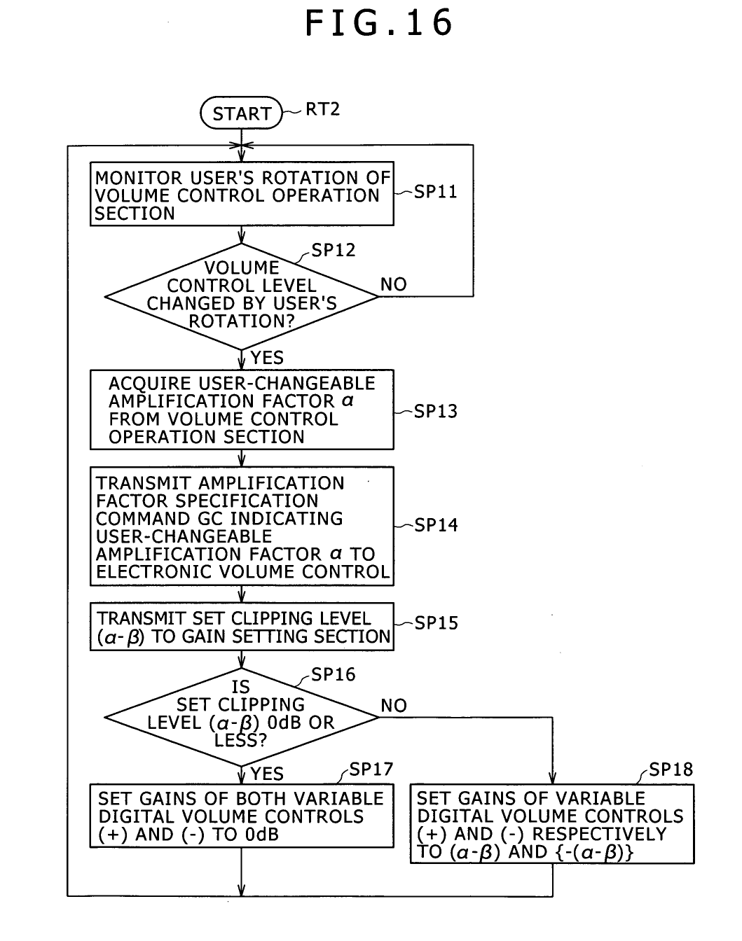

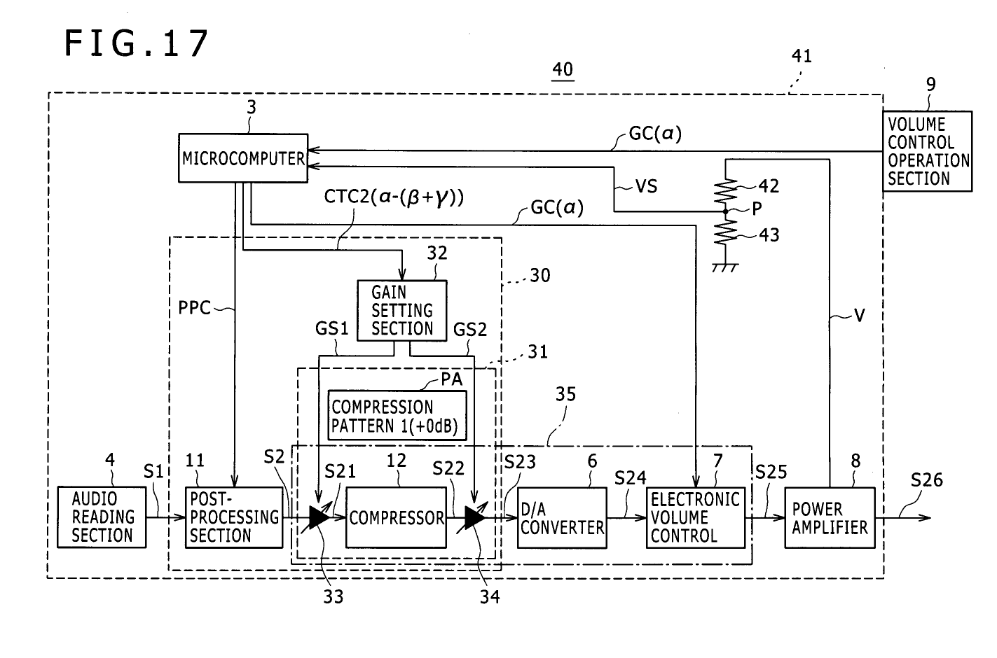

A detailed description will be given next of the steps for performing the above clipping prevention process with reference to the flowchart shown in FIG. 16. Practically, the microcomputer 3 begins with the initial step of a routine RT2. Next, the microcomputer 3 proceeds to step SP11 to monitor the user's rotation of the volume control operation section 9 and then proceeds on to step SP12.

In step SP12, the microcomputer 3 determines whether the volume control operation section 9 has been rotated by the user. If the result is negative in step SP12, this means that the volume control operation section 9 has not been rotated. At this time, the microcomputer 3 returns to step SP11 to wait until the volume control operation section 9 is rotated by the user.

In contrast, when the result is affirmative in step SP12, this means that the user-changeable amplification factor α has been changed as a result of the rotation of the volume control operation section 9 by the user. At this time, the microcomputer 3 proceeds to step SP13.

Incidentally, when the microcomputer 3 determines in step SP12 for the first time after initiating the clipping prevention process whether the volume control operation section 9 has been rotated by the user, it is assumed that the result is affirmative. As a result, the microcomputer 3 proceeds to next step SP13.

In step SP13, the microcomputer 3 acquires the amplification factor specification command GC indicating the user-changeable amplification factor α from the volume control operation section 9 and proceeds to next step SP14.

In step SP14, the microcomputer 3 sends the amplification factor specification command GC acquired from the volume control operation section 9 to the electronic volume control 7 to finalize the amplification factor of the same control 7 and then proceeds to next step SP15.

In step SP15, the microcomputer 3 subtracts the maximum amplification factor for 0 dB reproduction β stored in advance in the ROM from the user-changeable amplification factor α indicated by the amplification factor specification command GC acquired from the volume control operation section 9. Then, the microcomputer 3 sends the clipping level transmission command CTC1 to the gain setting section 32 of the DSP 30. The same command CTC1 indicates the set clipping level (α−β) obtained by subtracting the maximum amplification factor for 0 dB reproduction β from the user-changeable amplification factor α. Then, the microcomputer 3 proceeds to next step SP16.

In step SP16, the gain setting section 32 determines whether the set clipping level (α−β) indicated by the clipping level transmission command CTC1 supplied from the microcomputer 3 is 0 dB or less. The gain setting section 32 proceeds to next step SP17 when the result is affirmative.

In step SP17, the gain setting section 32 sends the gain signal GS1 to the variable digital volume control (+) 33. The same signal GS1 indicates 0 dB as the gain. This sets 0 dB as the gain of the variable digital volume control (+) 33.

Further, the gain setting section 32 sends the gain signal GS2 to the variable digital volume control (−) 34. The same signal GS2 indicates 0 dB as the gain. This sets 0 dB as the gain of the variable digital volume control (−) 34. Then, the gain setting section 32 returns to step SP11.

In contrast, if the result is negative in step SP16, the gain setting section 32 proceeds to step SP18.

In step SP18, the gain setting section 32 sends the gain signal GS1 to the variable digital volume control (+) 33. The same signal GS1 indicates the set clipping level (α−β) as the gain. This sets (α−β) as the gain of the variable digital volume control (+) 33.

Further, the gain setting section 32 sends the gain signal GS2 to the variable digital volume control (−) 34. The same signal GS2 indicates −(α−β) as the gain. This sets −(α−β) as the gain of the variable digital volume control (−) 34. Then, the gain setting section 32 returns to step SP11.

As described above, the car audio device 20 repeats steps SP11 to SP18 from power-on to power-off, thus preventing clipping of the analog audio signal S15 at all times.

### 2-4. Operation and Effects

In the above second embodiment, the car audio device 20 uses the gain setting section 32 to set the set clipping level (α−β), obtained by subtracting the maximum amplification factor for 0 dB reproduction β from the user-changeable amplification factor α, as the gain of the variable digital volume control (+) 33.

The car audio device 20 also uses the gain setting section 32 to set −(α−β) as the gain of the variable digital volume control (−) 34. The value −(α−β) is obtained by multiplying the set clipping level (α−β), obtained by subtracting the maximum amplification factor for 0 dB reproduction β from the user-changeable amplification factor α, by −1.

The car audio device 20 uses the variable digital volume control (+) 33 to amplify the digital audio signal S2 fed via the audio reading section 4 and post-processing section 11 with the gain (α−β) or the set clipping level.

Next, the car audio device 20 uses the compressor 12 to compress, based on the compression pattern 1 (+0 dB) PA, the level of the digital audio signal S11 amplified by the variable digital volume control (+) 33.

Next, the car audio device 20 uses the variable digital volume control (−) 34 to amplify the digital audio signal S12, compressed in level by the compressor 12, with the gain −(α−β).

Next, the car audio device 20 uses the D/A converter 6 to convert the digital audio signal S13, amplified by the variable digital volume control (−) 34, into an analog form.

Then, the car audio device 20 uses the electronic volume control 7 to amplify (attenuate) the analog audio signal S14, converted into an analog form by the D/A converter 6, with the user-changeable amplification factor α appropriate to the user's rotation of the volume control operation section 9.

This allows for the car audio device 20 to positively prevent clipping of the analog audio signal S15 outputted from the electronic volume control 7 irrespective of the level of the digital audio signal S1 or the user-changeable amplification factor α of the same control 7.

As a result, the analog audio signal S15 outputted from the electronic volume control 7 is not clipped in the car audio device 20, thus preventing clipping of the analog audio signal S6 outputted from the power amplifier 8. This makes it possible for the car audio device 20 to prevent clipping of the audio sound which will be output via the speaker.

Further, the car audio device 20 can perform the signal level compression for the digital audio signal S2 at the sampling rate of the DSP 30. This ensures fast gain control, thus making it possible to control the gain without giving a sense of discomfort to the user.

Still further, the car audio device 20 does not need to store in advance the plurality of compression patterns 1 (+0 dB) PA to 11 (+10 dB) PK as does the car audio device 1 according to the first embodiment. Instead, the car audio device 20 needs only to store a single compression pattern or the compression pattern 1 (+0 dB) PA, thus providing reduced memory load.

In the car audio device 20 configured as described above, the signal is first amplified with the amplification factor (α−β) or the set clipping level obtained by subtracting the maximum amplification factor for 0 dB reproduction β from the user-changeable amplification factor α, next compressed in level and finally amplified with the gain obtained by multiplying the set clipping level (α−β) by −1. This allows for the car audio device 20 to control the gain fast without giving a sense of discomfort to the user.

### 3. Third Embodiment

### 3-1. Configuration of the Car Audio Device

As illustrated in FIG. 17 in which like components as those in FIG. 11 are denoted by the same reference symbols, a car audio device 40 according to a third embodiment has resistors 42 and 43 in addition to the components of the car audio device 20 according to the second embodiment.

The resistor 42 is, for example, 30 kΩ and has one of its terminals connected to the power amplifier 8 and the other terminal connected in series to the resistor 43. The resistor 43 is, for example, 10 kΩ and has its terminal, which is not connected to the resistor 42, grounded. A connection point P between the resistors 42 and 43 is connected to the microcomputer 3.

To reproduce music content stored in a medium such as a CD or external USB memory, the car audio device 40 uses the audio reading section 4 to read the digital audio signal S1 of the music content. Then, the audio reading section 4 outputs the digital audio signal S1, read from the CD, USB memory or other medium, to the post-processing section 11 of the DSP 30.

On the other hand, the microcomputer 3 sends the post-processing command PPC to the post-processing section 11 of the DSP 30. The post-processing command PPC is adapted to apply the sound quality effects, set in advance by the user, to the digital audio signal S1.

Further, the microcomputer 3 acquires the user-changeable amplification factor specification command GC from the volume control operation section 9 and sends the same command GC to the electronic volume control 7. The amplification factor specification command GC indicates the amplification factor α in the range from −20 dB to +20 dB according to the user's rotation of the volume control operation section 9.

Still further, the microcomputer 3 monitors a voltage level VS of the connection point P between the resistors 42 and 43. This means, therefore, that the microcomputer 3 monitors a voltage level V of the power amplifier 8 obtained by voltage division by the resistors 42 and 43.

Then, the microcomputer 3 calculates the voltage level V of the power amplifier 8 based on the voltage level VS of the connection point P between the resistors 42 and 43 and then calculates an output level change rate γ (not shown) of the power amplifier 8 equivalent to the difference between the voltage level V and a reference operating voltage Vref (12 V in this case).

Next, the microcomputer 3 subtracts the maximum amplification factor for 0 dB reproduction β stored in advance in the ROM and the calculated output level change rate γ from the user-changeable amplification factor α indicated by the amplification factor specification command GC acquired from the volume control operation section 9.

The microcomputer 3 sends a clipping level transmission command CTC2 to the gain setting section 32 of the DSP 30. The same command CTC2 indicates a varying clipping level (α−β+γ)) obtained by subtracting the maximum amplification factor for 0 dB reproduction β and the calculated output level change rate γ from the user-changeable amplification factor α.

The gain setting section 32 sends the gain signals GS1 and GS2 respectively to the variable digital volume controls (+) 33 and (−) 34 based on the clipping level transmission command CTC2 supplied from the microcomputer 3.

The post-processing section 11 applies post-processing to the digital audio signal S1 inputted from the audio reading section 4 based on the post-processing command PPC supplied from the microcomputer 3. The same section 11 outputs the resultant digital audio signal S2 to the variable digital volume control (+) 33.

The variable digital volume control (+) 33 amplifies the digital audio signal S2 inputted from the post-processing section 11 based on the gain signal GS1 supplied from the gain setting section 32 and outputs a resultant digital audio signal S21 to the compressor 12.

The compressor 12 compresses the level of the digital audio signal S21 inputted from the variable digital volume control (+) 33 using the compression pattern 1 (+0 dB) PA (FIG. 12) stored in the compressor unit 31.

Then, the compressor 12 outputs a resultant digital audio signal S22, obtained by the signal level compression, to the variable digital volume control (−) 34.

The variable digital volume control (−) 34 amplifies the digital audio signal S22 inputted from the compressor 12 based on the gain signal GS 2 supplied from the gain setting section 32 and outputs a resultant digital audio signal S23 to the D/A converter 6.

The D/A converter 6 converts the digital audio signal S23 inputted from the compressor 12 into an analog form and outputs a resultant analog audio signal S24 to the electronic volume control 7.

The electronic volume control 7 amplifies the analog audio signal S24 inputted from the D/A converter 6 with the use-changeable amplification factor α indicated by the amplification factor specification command GC supplied from the microcomputer 3 and outputs a resultant analog audio signal S25 to the power amplifier 8.

The power amplifier 8 amplifies the analog audio signal S25 inputted from the electronic volume control 7 with the predetermined amplification factor and outputs a resultant analog audio signal S26, obtained by the amplification, from an external speaker (not shown) in the form of an audio sound.

As described above, the car audio device 40 outputs the audio sound appropriate to the music content stored in a CD, USB memory or other medium via a speaker, thus allowing for the user to listen to the audio sound.

Incidentally, the car audio device 40 is powered by the vehicle's battery (not shown), and the power amplifier 8 operates at the battery voltage.

The power amplifier 8 amplifies the analog audio signal S25 of 10 dB inputted from the electronic volume control 7 with a predetermined fixed amplification factor and outputs an analog audio signal S26 at the level appropriate to the operating voltage of the power amplifier 8.

However, there is a likelihood that the voltage level V of the power amplifier 8 may change due, for example, to the variation of the battery voltage.

At this time, even in the event of a decline of the voltage level V, the power amplifier 8 amplifies the analog audio signal S25 inputted from the electronic volume control 7 with the fixed amplification factor. This may result in clipping of the resultant analog audio signal S26.

For this reason, the car audio device 40 uses the microcomputer 3 to monitor the voltage level V of the power amplifier 8, performing a clipping prevention process according to the change in the voltage level V.

### 3-2. Clipping Prevention Process

A description will be given below of a clipping prevention process adapted to prevent clipping of the analog audio signal S25 inputted from the electronic volume control 7 and the analog audio signal S26 outputted from the power amplifier 8 by way of a specific example. Here, a case will be described in which the output level change rate γ of the power amplifier 8 equivalent to the difference between the voltage level V and reference operating voltage Vref is −5 dB.

For example, the microcomputer 3 acquires the amplification factor specification command GC indicating that the user-changeable amplification factor α is, for example, +10 dB according to the user's rotation of the volume control operation section 9.

Further, the microcomputer 3 detects the voltage level VS of the connection point P and calculates the voltage level V of the power amplifier 8 based on the voltage level VS. Then, the microcomputer 3 calculates −5 dB as the output level change rate γ of the power amplifier 8 equivalent to the difference between the voltage level V and reference operating voltage Vref.

Then, the microcomputer 3 subtracts +10 dB, the maximum amplification factor for 0 dB reproduction β stored in advance in the ROM and −5 dB, the output level change rate γ of the power amplifier 8, from +10 dB, the user-changeable amplification factor α indicated by the amplification factor specification command GC acquired from the volume control operation section 9. The microcomputer 3 sends the clipping level transmission command CTC2 to the gain setting section 32 of the DSP 30. The same command CTC2 indicates the varying clipping level (α−β+γ)) obtained by the subtraction.

The gain setting section 32 sets +5 dB, the varying clipping level (α−β+γ)) indicated by the clipping level transmission command CTC2 supplied from the microcomputer 3, as the gain of the variable digital volume control (+) 33. Then, the gain setting section 32 sends the gain signal GS1 to the variable digital volume control (+) 33. The same signal GS1 indicates the gain (+5 dB).

The variable digital volume control (+) 33 amplifies the digital audio signal S2 inputted from the post-processing section 11 with the gain, indicated by the gain signal GS1 supplied from the gain setting section 32, or +5 dB and outputs the resultant digital audio signal S21 to the compressor 12.

The compressor 12 compresses the level of the digital audio signal S21 inputted from the variable digital volume control (+) 33 based on the compression pattern 1 (+0 dB) PA (FIG. 12) and outputs the resultant digital audio signal S22 to the variable digital volume control (−) 34.

On the other hand, the gain setting section 32 sets (−(α−((β+γ))) or −5 dB, the value obtained by multiplying the varying clipping level (α−(β+γ)) indicated by the clipping level transmission command CTC2 by −1, as the gain of the variable digital volume control (−) 34.

Then, the gain setting section 32 sends the gain signal GS2 to the variable digital volume control (−) 34. The same signal GS2 indicates the gain (−5 dB) of the variable digital volume control (−) 34.

The variable digital volume control (−) 34 amplifies the digital audio signal S22 inputted from the compressor 12 with the gain, indicated by the gain signal GS2 supplied from the gain setting section 32, or −5 dB. That is, the same control (−) 34 attenuates the same signal S22 5 dB. The same control (−) 34 outputs the resultant digital audio signal S23 to the electronic volume control 7.

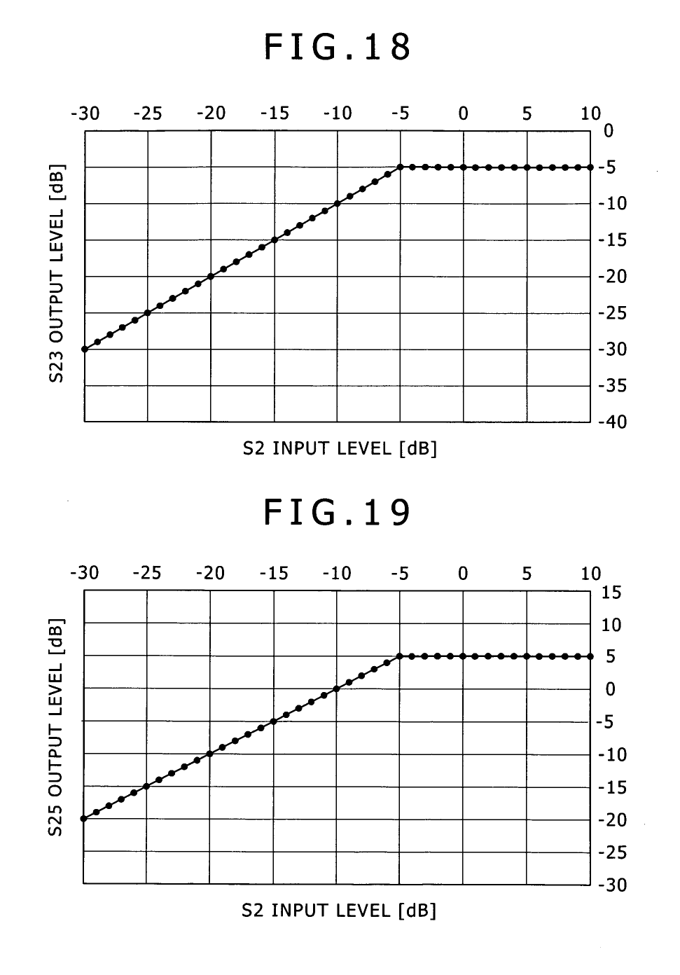

Here, FIG. 18 illustrates the input and output levels of the compressor unit 31 with the S2 input level representing the level of the digital audio signal S2 inputted to the compressor unit 31 and the S23 output level representing the level of the digital audio signal S23 outputted from the compressor unit 31.

As illustrated in FIG. 18, if the S2 input level is −5 dB or less, the compressor unit 31 outputs the digital audio signal S23 at the S23 output level which is the same level as the S2 input level.

In contrast, if the S2 input level is greater than −5 dB, the compressor unit 31 outputs the digital audio signal S23 at the S23 output level of −5 dB.

The electronic volume control 7 amplifies the analog audio signal S24 inputted from the compressor unit 31 via the D/A converter 6 with the user-changeable amplification factor α, indicated by the amplification factor specification command GC, or +10 dB.

Here, FIG. 19 illustrates the input and output levels of the amplification unit 35 with the S2 input level representing the level of the digital audio signal S2 inputted to the amplification unit 35 and the S25 output level representing the level of the analog audio signal S25 outputted from the amplification unit 35.

As illustrated in FIG. 19, if the S2 input level is −5 dB or less, the amplification unit 35 does not compress the level of the digital audio signal S21 with the compressor 12 and outputs the analog audio signal S25 at the S25 output level obtained by amplifying the S2 input level +10 dB.

In contrast, if the S2 input level is greater than −5 dB, the amplification unit 35 compresses the level of the digital audio signal S21 to −5 dB with the compressor 12 first. Then, the amplification unit 35 outputs the analog audio signal S25 at the S25 output level of 5 dB obtained by amplifying the S2 input level +10 dB with the electronic volume control 7.

As described above, the amplification unit 35 attenuates the analog audio signal S24 outputted from the electronic volume control 7, 5 dB in advance first and then inputs the resultant signal to the power amplifier 8 even if the output level change rate γ based on the operating voltage of the power amplifier 8 changes by −5 dB. This makes it possible for the car audio device 40 to positively prevent clipping of the analog audio signal S26 outputted from the power amplifier 8.

### 3-3. Clipping Prevention Process Steps

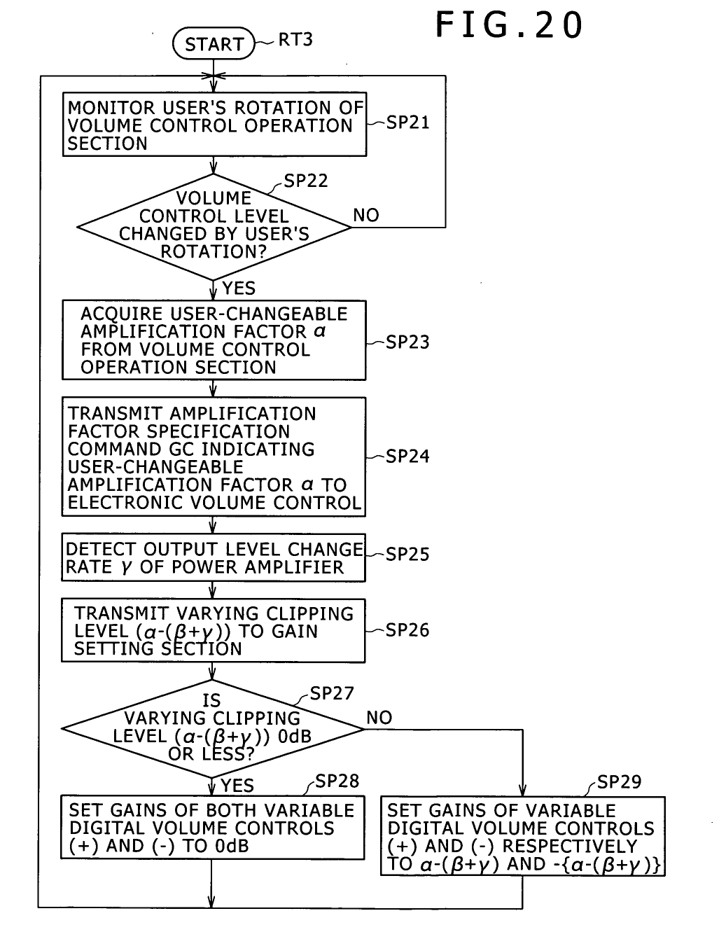

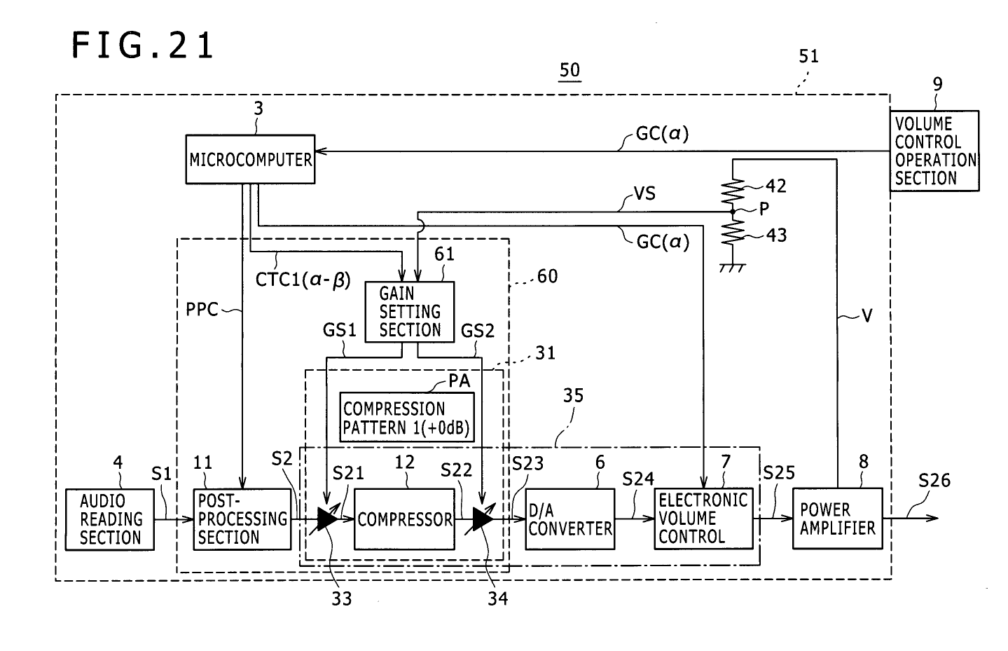

A detailed description will be given next of the steps for performing the above clipping prevention process with reference to the flowchart shown in FIG. 20. Practically, the microcomputer 3 begins with the initial step of a routine RT3. Next, the microcomputer 3 proceeds to step SP21 to monitor the user's rotation of the volume control operation section 9 and then proceeds on to step SP22.

In step SP22, the microcomputer 3 determines whether the volume control operation section 9 has been rotated by the user. If the result is negative in step SP22, this means that the volume control operation section 9 has not been rotated. At this time, the microcomputer 3 returns to step SP21 to wait until the volume control operation section 9 is rotated by the user.

In contrast, when the result is affirmative in step SP22, this means that the user-changeable amplification factor α has been changed as a result of the rotation of the volume control operation section 9 by the user. At this time, the microcomputer 3 proceeds to step SP23.

Incidentally, when the microcomputer 3 determines in step SP22 for the first time after initiating the clipping prevention process whether the volume control operation section 9 has been rotated by the user, it is assumed that the result is affirmative. As a result, the microcomputer 3 proceeds to next step SP23.

In step SP23, the microcomputer 3 acquires the amplification factor specification command GC indicating the user-changeable amplification factor α from the volume control operation section 9 and proceeds to next step SP24.

In step SP24, the microcomputer 3 sends the amplification factor specification command GC acquired from the volume control operation section 9 to the electronic volume control 7 to finalize the amplification factor of the same control 7 and then proceeds to next step SP25.

In step SP25, the microcomputer 3 detects the voltage level VS of the connection point P and calculates the voltage level V of the power amplifier 8 based on the voltage level VS. Then, the microcomputer 3 calculates the output level change rate γ of the power amplifier 8 equivalent to the difference between the voltage level V and reference operating voltage Vref and then proceeds to next step SP26.

In step SP26, the microcomputer 3 subtracts the maximum amplification factor for 0 dB reproduction β stored in advance in the ROM and the output level change rate γ calculated in step SP25 from the user-changeable amplification factor α indicated by the amplification factor specification command GC acquired from the volume control operation section 9.

Then, the microcomputer 3 sends the clipping level transmission command CTC2 to the gain setting section 32 of the DSP 30. The same command CTC2 indicates the varying clipping level (α−(β+γ)) obtained by subtracting the maximum amplification factor for 0 dB reproduction β and the output level change rate γ from the user-changeable amplification factor α. The microcomputer 3 proceeds to next step SP27.

In step SP27, the gain setting section 32 determines whether the varying clipping level (α−(β+γ)) indicated by the clipping level transmission command CTC2 supplied from the microcomputer 3 is 0 dB or less. The gain setting section 32 proceeds to next step SP28 when the result is affirmative.

In step SP28, the gain setting section 32 sends the gain signal GS1 to the variable digital volume control (+) 33. The same signal GS1 is adapted to bring the gain of the same control (+) 33 to 0 dB. This sets 0 dB as the gain of the same control (+) 33.

Further, the gain setting section 32 sends the gain signal GS2 to the variable digital volume control (−) 34. The same signal GS2 is adapted to bring the gain of the same control (−) 34 to 0 dB. This sets 0 dB as the gain of the same control (−) 34. Then, the gain setting section 32 returns to step SP21.

In contrast, if the result is negative in step SP27, the gain setting section 32 proceeds to step SP29. In step SP29, the gain setting section 32 sends the gain signal GS1 to the variable digital volume control (+) 33. The same signal GS1 is adapted to bring the gain of the same control (+) 33 to the varying clipping level (α−(β+γ)). This sets α−(β+γ) as the gain of the variable digital volume control (+) 33.

Further, the gain setting section 32 sends the gain signal GS2 to the variable digital volume control (−) 34. The same signal GS2 is adapted to bring the gain of the same control (−) 34 to (−(α−(β+γ))). This sets (−(α−(β+γ))) as the gain of the same control (−) 34. Then, the gain setting section 32 returns to step SP21.

As described above, the car audio device 40 repeats steps SP21 to SP29 from power-on to power-off, thus preventing clipping of the analog audio signal S26 at all times.

### 3-4. Operation and Effects

In the above third embodiment, the car audio device uses the gain setting section 32 to set the varying clipping level (α−((β+γ)), obtained by subtracting the maximum amplification factor for 0 dB reproduction β and the output level change rate γ appropriate to the voltage level V of the power amplifier 8 from the user-changeable amplification factor α, as the gain of the variable digital volume control (+) 33.

Further, the car audio device 40 uses the gain setting section 32 to set (−(α−((β+γ))), the value obtained by multiplying the varying clipping level (α−((β+y)) by −1, as the gain of the same control (−) 34. The varying clipping level (α−(β+γ)) is obtained by subtracting the maximum amplification factor for 0 dB reproduction β and the output level change rate γ from the user-changeable amplification factor α.

Then, the car audio device 40 uses the variable digital volume control (+) 33 to amplify the digital audio signal S2 obtained via the audio reading section 4 and post-processing section 11 with the gain (α−(β+γ)) or the set clipping level.

Next, the car audio device 40 uses the compressor 12 to compress, based on the compression pattern 1 (+0 dB) PA, the level of the digital audio signal S21 amplified by the variable digital volume control (+) 33.

Next, the car audio device 40 uses the variable digital volume control (−) 34 to amplify the digital audio signal S22, compressed in level by the compressor 12, with the gain (−(α−(β+γ))).

Next, the car audio device 40 uses the D/A converter 6 to convert the digital audio signal S23, amplified by the variable digital volume control (−) 34, into an analog form.

Then, the car audio device 40 uses the electronic volume control 7 to amplify the analog audio signal S24, converted into an analog form by the D/A converter 6, with the user-changeable amplification factor α appropriate to the user's rotation of the volume control operation section 9.

Therefore, the car audio device 40 performs the clipping prevention process based on the user-changeable amplification factor α, maximum amplification factor for 0 dB reproduction β and output level change rate γ even in the event of a change in the output level change rate γ, thus preventing clipping of the analog audio signal S26 outputted from the power amplifier 8.

This makes it possible for the car audio device 40 to prevent clipping of the audio sound which will be output via the speaker.

In the car audio device 40 configured as described above, the signal is first amplified with the amplification factor (α−(β+γ)) or the varying clipping level obtained by subtracting, the maximum amplification factor for 0 dB reproduction β and the output level change rate γ from the user-changeable amplification factor α, next compressed in level and finally amplified with the gain obtained by multiplying the varying clipping level (α−((β+γ)) by −1. This allows for the car audio device 40 to control the gain fast without giving a sense of discomfort to the user.

### 4. Other Embodiments

### 4-1. Other Embodiment 1

In the above third embodiment, a case was described in which the microcomputer 3 monitored the voltage level V of the power amplifier 8. However, the present invention is not limited thereto. Instead, as illustrated in FIG. 21 in which like components as those in FIG. 17 are denoted by the same reference symbols, a gain setting section 61 of a DSP 60 of a car audio device 50 may monitor the voltage level V of the power amplifier 8.

More specifically, the microcomputer 3 subtracts the maximum amplification factor for 0 dB reproduction β stored in the ROM from the user-changeable amplification factor α indicated by the amplification factor specification command GC acquired from the volume control operation section 9.

Then, the microcomputer 3 sends the clipping level transmission command CTC1 to the gain setting section 61 of the DSP 60. The same command CTC1 indicates the set clipping level (α−β) obtained by subtracting the maximum amplification factor for 0 dB reproduction β from the user-changeable amplification factor α.

The gain setting section 61 calculates the voltage level V of the power amplifier 8 based on the voltage level VS of the connection point P between the resistors 42 and 43 and then calculates the output level change rate γ of the power amplifier 8 equivalent to the difference between the voltage level V and reference operating voltage Vref.

Then, the gain setting section 61 calculates the varying clipping level (α−(β+γ)) by subtracting the output level change rate γ of the power amplifier 8 from the set clipping level (α−β) indicated by the clipping level transmission command CTC1 supplied from the microcomputer 3.

Then, the gain setting section 61 sets the varying clipping level (α−(β+γ)) as the gain of the variable digital volume control (+) 33 and also sets the value, obtained by multiplying the varying clipping level (α−((β+γ)) by −1, as the gain of the variable digital volume control (−) 34.

This allows for the car audio device 50 to perform a clipping prevention process similar to that performed by the car audio device 40 according to the third embodiment.

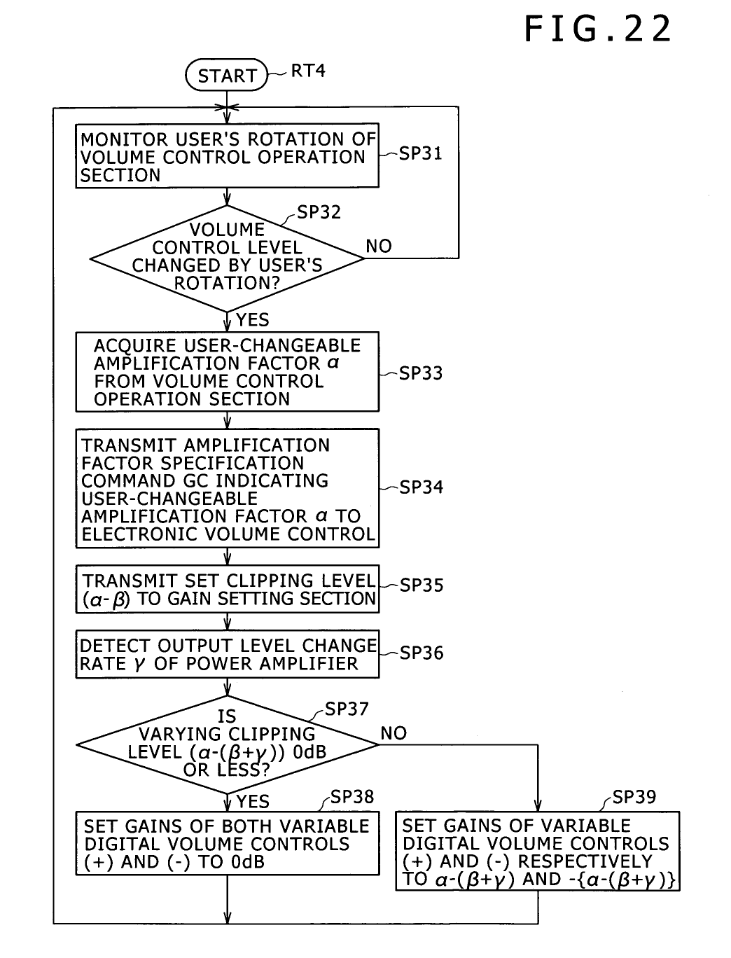

A specific description will be given below with reference to the flowchart shown in FIG. 22. Practically, the microcomputer 3 begins with the initial step of a routine RT4. Next, the microcomputer 3 proceeds to step SP31 to monitor the user's rotation of the volume control operation section 9 and then proceeds on to step SP32.

In step SP32, the microcomputer 3 determines whether the volume control operation section 9 has been rotated by the user. If the result is negative in step SP32, this means that the volume control operation section 9 has not been rotated. At this time, the microcomputer 3 returns to step SP31 to wait until the volume control operation section 9 is rotated by the user.

In contrast, when the result is affirmative in step SP32, this means that the user-changeable amplification factor α has been changed as a result of the rotation of the volume control operation section 9 by the user. At this time, the microcomputer 3 proceeds to step SP33.

Incidentally, when the microcomputer 3 determines in step SP32 for the first time after initiating the clipping prevention process whether the volume control operation section 9 has been rotated by the user, it is assumed that the result is affirmative. As a result, the microcomputer 3 proceeds to next step SP33.

In step SP33, the microcomputer 3 acquires the amplification factor specification command GC indicating the user-changeable amplification factor α from the volume control operation section 9 and proceeds to next step SP34.

In step SP34, the microcomputer 3 sends the amplification factor specification command GC acquired from the volume control operation section 9 to the electronic volume control 7 to finalize the amplification factor of the same control 7 and then proceeds to next step SP35.

In step SP35, the microcomputer 3 subtracts the maximum amplification factor for 0 dB reproduction β stored in advance in the ROM from the user-changeable amplification factor α indicated by the amplification factor specification command GC acquired from the volume control operation section 9.

Then, the microcomputer 3 sends the clipping level transmission command CTC1 to the gain setting section 61 of the DSP 60. The same command CTC1 indicates the set clipping level (α−β) obtained by subtracting the maximum amplification factor for 0 dB reproduction β from the user-changeable amplification factor α. Then, the microcomputer 3 proceeds to next step SP36.

In step SP36, the gain setting section 61 detects the voltage level VS of the connection point P and calculates the voltage level V of the power amplifier 8 based on the voltage level VS. Then, the gain setting section 61 calculates the output level change rate γ of the power amplifier 8 equivalent to the difference between the voltage level V and reference operating voltage Vref and proceeds to step SP37.

In step SP37, the gain setting section 61 subtracts the output level change rate γ calculated in step SP36 from the set clipping level (α−β) indicated by the clipping level transmission command CTC1 supplied from the microcomputer 3. Then, the gain setting section 61 determines whether the varying clipping level (α−(β+γ)) obtained by the subtraction is 0 dB or less. When the result is affirmative, the gain setting section 61 proceeds to next step SP38.

In step SP38, the gain setting section 61 sends the gain signal GS1 to the variable digital volume control (+) 33. The same signal GS1 is adapted to bring the gain of the same control (+) 33 to 0 dB. This sets 0 dB as the gain of the same control (+) 33.

Further, the gain setting section 61 sends the gain signal GS2 to the variable digital volume control (−) 34. The same signal GS2 is adapted to bring the gain of the same control (−) 34 to 0 dB. This sets 0 dB as the gain of the same control (−) 34. Then, the gain setting section 32 returns to step SP31.

In contrast, if the result is negative in step SP37, the gain setting section 61 proceeds to step SP39. In step SP39, the gain setting section 61 sends the gain signal GS1 to the variable digital volume control (+) 33. The same signal GS1 is adapted to bring the gain of the same control (+) 33 to the varying clipping level (α−(β+γ)). This sets α−(β+γ) as the gain of the variable digital volume control (+) 33.

Further, the gain setting section 61 sends the gain signal GS2 to the variable digital volume control (−) 34. The same signal GS2 is adapted to bring the gain of the same control (−) 34 to (−(α−(β+γ))). This sets (−(α−(β+γ))) as the gain of the same control (−) 34. Then, the gain setting section 61 returns to step SP31.

As described above, the car audio device 60 repeats steps SP31 to SP39 from power-on to power-off, thus preventing clipping of the analog audio signal S25 at all times.

### 4-2. Other Embodiment 2

Further, in the above third embodiment, the gain setting section 32 sets 0 dB as the gains of the variable digital volume controls (+) 33 and (−) 34 in step SP28 of the clipping prevention process steps of the routine RT3 when the varying clipping level (α−(β+γ)) is 0 dB or less.

However, the present invention is not limited thereto. Instead, the gain setting section 32 may set the varying clipping level (α−(β+γ)) as the gain of the variable digital volume control (+) 33, and (−(α−((β+γ))) as the gain of the variable digital volume control (−) 34 when the varying clipping level (α−(β+γ)) is 0 dB or less.

This allows for the car audio device 40 to more effectively use the voltage level V of the power amplifier 8 if the same level V increases.

### 4-3. Other Embodiment 3

Further, in the first embodiment, a case was described in which the pattern selector 13 stored the compression patterns 1 (+0 dB) PA to 11 (+10 dB) PK, one dB apart from one another, in advance. However, the present invention is not limited thereto. Instead, the pattern selector 13 may store the patterns which are, for example, 0.5 dB or 2 dB apart from one another.

### 4-4. Other Embodiment 4

Still further, in the above first to third embodiments, a case was described in which the clipping prevention processes of the routines RT1 to RT3 were performed according to the application program stored in advance in the ROM of the microcomputer 3. However, the present invention is not limited thereto. Instead, the microcomputer 3 may perform the clipping prevention processes of the routines RT1 to RT3 according to an application program installed from a storage medium, downloaded from the Internet or installed via other various routes.

Still further, in the above embodiments, a case was described in which the car audio device 1 serving as the clipping prevention device of the present invention included the compressor 12 as a compression section, the D/A converter as a digital-analog conversion section, the electronic volume control 7 as an electronic volume control and the microcomputer 3 as a control section. However, the present invention is not limited thereto. Instead, the clipping prevention device may include a compression section, digital-analog conversion section, electronic volume control and control section configured in other various manners.

The clipping prevention device of the present embodiment is applicable not only to car audio devices but also to digital audio reproduction equipment incorporated in stationary audio players and various other devices.

The present application contains subject matter related to that disclosed in Japanese Priority Patent Application JP 2008-307523 filed with the Japan Patent Office on Dec. 2, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A clipping prevention device, comprising:
a compression section adapted to compress an input digital audio signal level;
a digital-analog conversion section adapted to operate at a predetermined first operating voltage and convert the digital audio signal, compressed by the compression section, into an analog audio signal;
an electronic volume control adapted to operate at a second operating voltage higher than the first operating voltage and amplify or attenuate the analog audio signal with a user-changeable amplification factor appropriate to the user's rotation of an operator; and
a control section adapted to calculate a clipping level based on the maximum amplification factor of the electronic volume control and the user-changeable amplification factor, the maximum amplification factor of the electronic volume control being determined when the analog audio signal at the maximum signal level based on the first operating voltage is amplified to the maximum signal level based on the second operating voltage, the control section also adapted to control the compression section so that the signal is compressed according to the clipping level so as to prevent clipping of the analog audio signal amplified or attenuated by the electronic volume control.

2. The clipping prevention device of claim 1, comprising
a pattern selector adapted to store a plurality of compression patterns and select one of the plurality of compression patterns according to the clipping level, wherein
the compression section compresses the level of the digital audio signal according to the compression pattern selected by the pattern selector.

3. The clipping prevention device of claim 1, comprising:
a gain setting section adapted to set the clipping level sent from the control section as a gain;
an amplification section adapted to amplify the digital audio signal with the gain set by the gain setting section; and
an attenuation section adapted to attenuate the digital signal, compressed by the compression section, with the gain set by the gain setting section, wherein
the compression section compresses the digital audio signal, amplified by the amplification section, according to a predetermined compression pattern.

4. The clipping prevention device of claim 3, comprising
a power amplifier adapted to amplify an analog audio signal, amplified or attenuated by the electronic volume control, with a predetermined fixed amplification factor, wherein
the gain setting section sets, as the gain, a varying clipping level which is based on the user-changeable amplification factor, the maximum amplification factor and an amplification factor equivalent to the change in operating voltage of the power amplifier.

5. A clipping prevention method, comprising the steps of:
compressing the level of an input digital audio signal using a compression section;
converting the digital audio signal, compressed by the compression section, into an analog audio signal using a digital-analog conversion section which operates at a predetermined first operating voltage;
amplifying or attenuating the analog audio signal with a user-changeable amplification factor appropriate to the user's rotation of an operator with an electronic volume control which operates at a second operating voltage higher than the first operating voltage; and
calculating a clipping level based on the maximum amplification factor of the electronic volume control and the user-changeable amplification factor, the maximum amplification factor of the electronic volume control being determined when the analog audio signal at the maximum signal level based on the first operating voltage is amplified to the maximum signal level based on the second operating voltage, controlling the compression section so that the signal is compressed according to the clipping level so as to prevent clipping of the analog audio signal amplified or attenuated by the electronic volume control.
